(19) United States
(12) Patent Application Publication
(10) Pub. No.: US 2009/0065935 A1
(43) Pub. Date: Mar. 12, 2009

(54) SYSTEMS AND METHODS FOR BALL GRID ARRAY (BGA) ESCAPE ROUTING

(75) Inventor: MICHAEL JOHN BAZATA, ELIZABETH, CO (US)

Correspondence Address: INGRASSIA FISHER & LORENZ, P.C. (ES), 7010 E. COCHISE ROAD, SCOTTSDALE, AZ, 85253, US

(73) Assignee: ECHOSTAR TECHNOLOGIES CORPORATION, Englewood, CO (US)

(21) Appl. No.: 11/851,193

(22) Filed: Sep. 6, 2007

(51) Int. Cl. H01L 23/52; H01L 21/44

(52) U.S. Cl. 257/738; 438/613; 257/E23.141; 257/E21.476

(57) ABSTRACT

A ball grid array (BGA) package and its corresponding printed circuit board incorporate an improved escape routing scheme. The substrate includes a plurality of conductive pads having a periphery defined by a predetermined edge pattern forming routing channels therebetween. A plurality of signal lines connected to a subset of the conductive pads extends beyond the periphery through the routing channels. The predetermined pattern may, for example, be a right triangle repeating with a periodicity along the periphery of the array, wherein the right triangle has a first side defined by a number of rows in the array, and a second side, perpendicular to the first, defined by a number of layers in the array.

### TECHNICAL FIELD

The embodiments described herein generally relate to semiconductor packaging and interconnects, and more particularly relate to ball grid arrays with improved routing of signal lines.

### BACKGROUND

The ball grid array (BGA) package has achieved wide popularity in the semiconductor packaging industry due in part to its improved board-space efficiency, excellent thermal performance, and low-profile geometry. In general, a BGA is a type of surface-mount package in which one side of the package includes an array of solder balls attached to a corresponding array of contacts on a substrate. This substrate may be a printed circuit board (PCB), an epoxy/glass leadframe, or the like. The internal chip is connected to the array of contacts through wire bonds, wire bond pads, metal traces, routing vias, and other known interconnect methods.

During mounting, the packaged device is placed on another PCB or substrate that includes a corresponding array of pads (e.g., copper pads) and is then heated (e.g., via a reflow oven or infrared source) such that the solder balls on the underside of the package melt, thereby bonding the package substrate to the PCB. The array of solder balls (and likewise, the array of contacts) is generally a square or rectangular grid with a pitch (i.e., distance between midpoints of adjacent pads) that is suitable for the particular application.

The well-known “Rent's rule” states, generally, that as the number of gates on a single die increases, the number of input/output lines required to interface to the outside world increases by a power function. Accordingly, one challenge presented by prior art BGA packaging techniques is the task of routing all of the required signal, power, and ground pins to the external PCB board in modern semiconductor packages. This challenge, sometimes referred to as “escape routing,” is particularly difficult in the context of integrated circuit devices, which typically have a large number of such pins.

To achieve escape routing, it is common for the outer rows (for example, two to four of the outer rows) within the array to contain all pins that require escape routing. The number of metal traces on the PCB that can be routed between adjacent contacts is limited, however, by the width of the traces, the size (e.g., diameter) of the contacts, and the design rules associated therewith. Thus, as the interconnect complexity of modern BGA packages increases, it has become increasingly difficult to route traces from the internal contacts of the array while still achieving suitable design tolerances for number of traces that can reasonably fit between adjacent contacts. As the number of pins in a BGA increases, the number of rows and layers required for escape routing increases non-linearly.

Accordingly, it is desirable to methods and apparatus for improving the routing of signal lines associated with BGA packages. Other desirable features and characteristics of the various embodiments will become apparent from the subsequent detailed description and the appended claims, taken in conjunction with the accompanying drawings and the foregoing technical field and background.

### BRIEF SUMMARY

Methods and apparatus in accordance with various embodiments provide a BGA package and/or PCB system incorporating an improved escape routing scheme. In accordance with one embodiment, the PCB or substrate includes a plurality of conductive pads corresponding to the array pattern of the BGA package, and has a periphery defined by a predetermined edge pattern forming routing channels therebetween. A plurality of signal lines connected to a subset of the conductive pads extends beyond the periphery through the routing channels. The predetermined pattern may, for example, be a right triangle repeating with a periodicity along the periphery of the array, wherein the right triangle has a first side defined by a number of rows in the array, and a second side defined by a number of layers in the array.

### BRIEF DESCRIPTION OF THE DRAWINGS

Various embodiments will hereinafter be described in conjunction with the following drawing figures, wherein like numerals denote like elements, and

FIG. 1 schematically depicts a portion of a typical prior art BGA pattern;

FIG. 2 schematically depicts a BGA pattern in accordance with one embodiment;

FIG. 3 depicts exemplary routing channels and metal traces for the embodiment shown in FIG. 2; and

FIG. 4 depicts a generalized array pattern and associated routing channels in accordance with various embodiments.

### DETAILED DESCRIPTION

The various embodiments described herein generally relate to a ball grid array (BGA) package design whose geometry permits improved routing of signal lines external to the array. In this regard, the following detailed description is merely exemplary in nature and is not intended to limit the described embodiments or the application and uses of the described embodiments. Similarly, there is no intention to be bound by any expressed or implied theory presented in the preceding technical field, background, brief summary or the following detailed description.

In the interest of conciseness, conventional techniques, structures, and principles known by those skilled in the art may not be described herein, including, for example, standard semiconductor packaging techniques. For simplicity and clarity of illustration, the drawing figures depict the general structure and/or manner of construction of the various embodiments. Descriptions and details of well-known features and techniques may be omitted to avoid unnecessarily obscuring other features. Elements in the drawings figures are not necessarily drawn to scale, and thus the dimensions of some features may be exaggerated relative to other elements to assist improve understanding of the example embodiments.

Terms of enumeration such as “first,” “second,” “third,” and the like may be used for distinguishing between similar elements and not necessarily for describing a particular spatial or chronological order. These terms, so used, are interchangeable under appropriate circumstances. Unless expressly stated otherwise, “connected” or “connecting” means that one element/node/feature is directly joined to (or directly communicates with) another element/node/feature, but not necessarily mechanically. Likewise, “coupled” or “coupling” means that one element, node, or feature is directly or indirectly joined to (or directly or indirectly communicates with) another element, node, or feature, but not necessarily mechanically. The terms “comprise,” “comprising,” “include,” “have” and any variations thereof are used synonymously to denote non-exclusive inclusion. The terms “left,” right,” “in,” “out,” “front,” “back,” “up,” “down,” and other such directional terms are used to describe relative positions, not necessarily absolute positions in space. The term “exemplary” is used in the sense of “example,” rather than “ideal.”

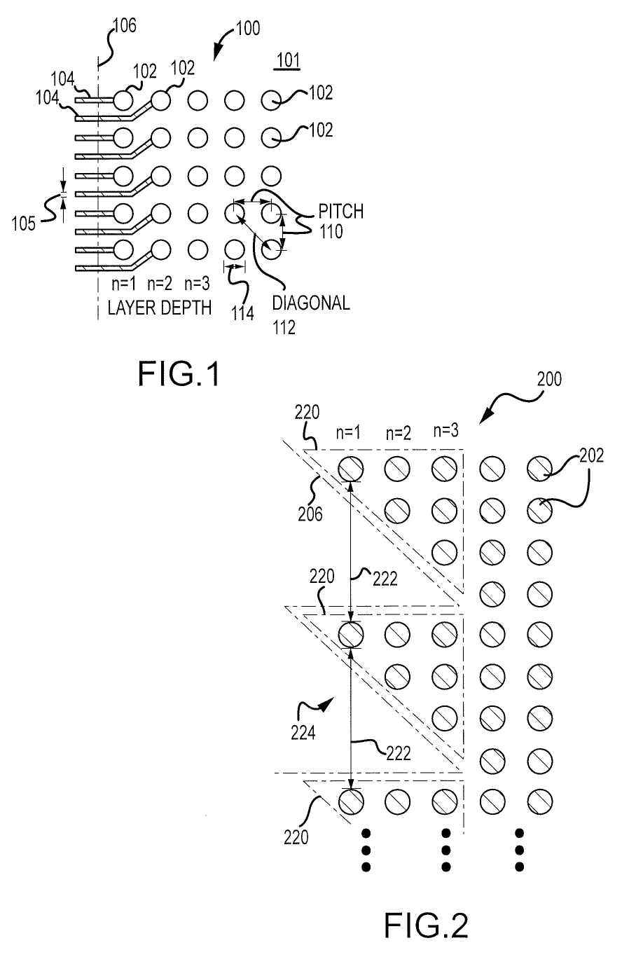

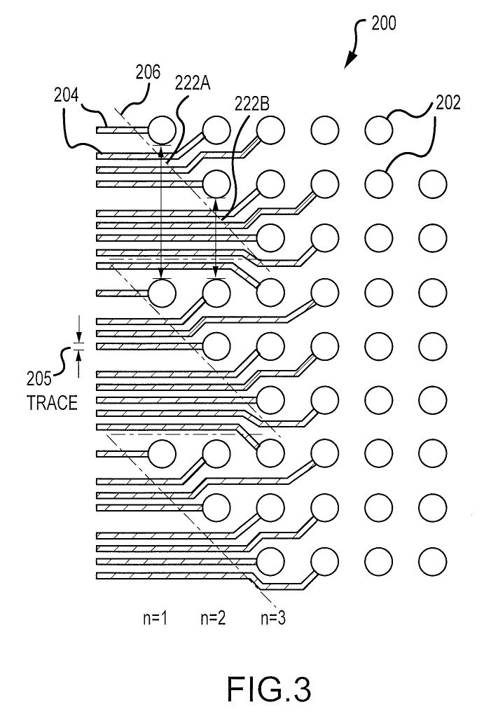

In general, the various embodiments described herein relate to a BGA package and associated substrate whose matching arrays have a triangular or “staggered” edge pattern configured to provide improved escape efficiency. That is, comparing briefly the contact patterns shown in FIGS. 1 and 3, a BGA pattern 200 in accordance with one embodiment has a periphery 206 defined by a predetermined edge pattern (in this embodiment, a right-triangular edge pattern), rather than a linear edge pattern as shown in FIG. 1. This design provides improved escape efficiency in that a greater number of traces 204 can be routed to the periphery 206 from interior layers of pads 202.

More particularly, FIG. 1 depicts a portion of a typical prior art BGA pattern 100 arranged on a substrate 101 in a regular rectangular array, wherein, according to standard terminology, the vertical columns are referred to as “layers,” and the horizontal rows are referred to simply as “rows.” The array pattern 100 is configured to match (in number and shape) the corresponding pattern of the BGA package to which it will be mounted. Thus, the term “array pattern” may be used at various points herein to refer to both the pattern of solder balls on the BGA as well as the pattern of conductive pads on the corresponding PCB or substrate.

In this regard, the acronym “BGA” as used herein denotes any of the various ball grid array designs now known or developed in the future. Such designs include, for example, the plastic ball grid array (PBGA), the ceramic ball grid array (CBGA), and the fine ball grid array (FBGA). Conversely, particular type of BGA designs may be discussed in connection with various embodiments, and is done so without loss of generality.

As can be seen, metal traces (alternatively, “signal lines” or simply “traces”) 104 exit from the periphery contacts 102 adjacent the outer edge 106 of the array pattern 100. More particular, the first two layers of contacts 102 (corresponding to layer depths n=1 and n=2) have metal traces connected to and extending therefrom, wherein those from layer depth n=2 are routed between adjacent contacts 102 in layer depth n=1.

In this illustration, the pitch 110 (i.e., distance between centers) is the same in both the horizontal and vertical directions, though this need not be the case. The array pattern is also characterized by a diagonal 112 and a pad dimension 114. As mentioned previously above, the number of traces that can exit through layer depth n=1 is limited by the pitch 110, the pad dimension 114, and the trace width 105.

FIG. 2 depicts an array pattern 200 having a periphery 206 defined by a predetermined edge pattern 206 forming routing channels 222 therebetween. In the interest of clarity, the set of pads 200 is intended to represent only a portion of the pads lying along the edge of an exemplary array pattern. The conductive pads 202 are deposited or otherwise formed on a substrate 201 (e.g, PCB, or the like), and may have any convenient shape. Those skilled in the art recognize that a typical BGA will have a large number of such contact pads (e.g., 86 pads, 313 pads, etc.).

Array pattern 200 is illustrated as a regular rectangular array having horizontal and vertical pitches that are equal and constant. The present invention, however, is not so limited. Array 200 may be regular, irregular, rectilinear, curvilinear, or any combination thereof. Furthermore, the horizontal and vertical pitches between pads 200 need not be equal.

The predetermined edge pattern 206 may have any suitable shape. In one embodiment, for example, edge pattern 206 is a right triangle having one side defined by a number of rows, and another side defined by a number of layers. In the illustrated embodiment, for example, edge pattern 206 is an isosceles right triangle defined by 6 pads, with 3-pad sides.

Stated another way, array 200 may be thought of as having contacts “removed” from a theoretical rectangular array. That is, a triangle of three contacts (in region 224) has been removed along the edge of what would otherwise be a standard rectangular array having a constant pitch. These “removed” pads form a triangle that is the rectangular complement of triangular edge pattern 220.

Referring to FIG. 3, the substrate to which the BGA package may be attached includes a plurality of signal lines 204 connected to a subset of conductive pads 200. This subset includes two or more outer layers of pads 200 (i.e., n=1, 2, . . . ). The greater the layer depth, the more metal traces that can be routed beyond the periphery of the array, as will be discussed in further detail below.

Signal lines 204 extend beyond periphery 206 through routing channels 222. It can be seen that the predetermined pattern of pads along periphery 206 allows a greater number of traces 204 to escape. In the illustrated embodiment, five traces 204 exit from layer n=3 through routing channel 222B, while eight traces 204 exit from layer n=2 through routing channel 222A. It is presumed in this embodiment that two traces can routed between diagonals, and one trace can be routed between adjacent pads. Depending upon, among other things, the pitch and dimensions of pads 202 and traces 204, this number may be lower or higher.

The embodiment illustrated in FIG. 3 is not necessarily drawn to scale; however, in one embodiment, array pattern 200 has a constant pitch of 39 mils, and a pad dimension of 20 mils, resulting in a 35 mil diagonal distance between pads. In such an embodiment, with traces having a 5 mil width, and 5 mils between traces; routing channel 222B is then 58 mils, and routing channel 222A is 97 mils.

In one embodiment, the predetermined pattern repeats with a periodicity R along the edge of the array 200. For example, the embodiment shown in FIG. 3 has a periodicity of three, as the pattern repeats every three rows. Stated another way, pads have been “removed” from R-1 rows (i.e., with respect to a uniform rectangular array).

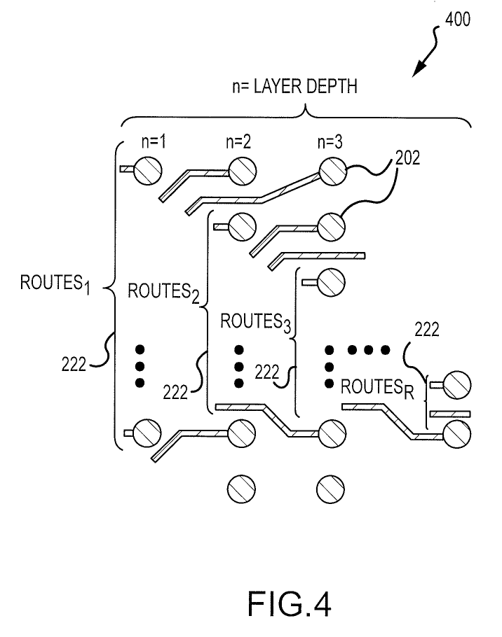

FIG. 4 depicts a generalized pad array 400 with routing channels ROUTESᵢ (222), where i is the layer depth. Given CHANNEL_ROUTESₙ, as the number of traces that can be routed through a particular routing channel, HROUTABLE is the number of traces that can be routed horizontally between balls, and DROUTABLE as the number of traces that can be routed diagonally between balls, the number of traces that can be routed out from layer n, where n>1 and n<R, is given by:

ROUTESₙ=(ROUTESₙ₊₁+2+DROUTABLE), if CHANNEL_ROUTESₙ≧(ROUTESₙ₊₁+1+DROUTABLE), and

ROUTESₙ=(CHANNEL_ROUTESₙ₊₁), if CHANNEL_ROUTESₙ<(ROUTESₙ₊₁+1+DROUTABLE).

Similarly, the number of traces that can be routed out from layer 1 is given by:

ROUTES₁=(ROUTES₂+1+DROUTABLE), if CHANNEL_ROUTES₁≧(ROUTES₂+DROUTABLE), and

ROUTES₁=(CHANNEL_ROUTES₁+1), if CHANNEL_ROUTES₁<(ROUTES₂+DROUTABLE).

Finally, the number of traces that can be routed out from layer R (where R is the periodicity of the triangular predetermined edge pattern) is given by:

ROUTES_{R}=HROUTE+1

Accordingly, the escape efficiency of the array can be computed as:

$$EFFICENCY = \frac{{ROUTES}_{1} * TRACE * 2}{R * PITCH} ,$$

where TRACE is the width of the traces (205 in FIG. 3), and PITCH is the pitch of the contacts, as previously described. Furthermore, the number of traces that can be routed out per row is given by:

ROUTES_PER_ROW=ROUTES₁/R

It has been determined by the present inventors that advantageous escape efficiencies can be achieved utilizing an array design such as that shown in the illustrated embodiments. In a particular embodiment, for example, where the pitch is 39 mils, the pad dimension is 18 mils, and the trace width is 5 mils, the efficiencies listed in Table 1 are obtained.

TABLE 1

| R | Escape Efficiency (%) | Routes per Row |
|---|---|---|
| 2 | 64.1 | 2.50 |
| 3 | 76.9 | 3.00 |
| 4 | 83.3 | 3.25 |
| 5 | 87.2 | 3.40 |
| 6 | 89.7 | 3.50 |
| 7 | 91.6 | 3.57 |
| 8 | 92.9 | 3.63 |

Similarly, in an embodiment where the trace width is 6 mils (allowing only 2 traces between diagonals, rather than 3), the efficiencies shown in Table 2 are obtained.

TABLE 2

| R | Escape Efficiency (%) | Routes per Row |
|---|---|---|
| 2 | 76.9 | 2.50 |
| 3 | 82.1 | 2.67 |
| 4 | 84.6 | 2.75 |
| 5 | 92.3 | 3.00 |
| 6 | 92.3 | 3.00 |
| 7 | 92.3 | 3.00 |
| 8 | 92.3 | 3.00 |

While at least one exemplary embodiment has been presented in the foregoing detailed description, it should be appreciated that a vast number of variations exist. The foregoing detailed description will provide those skilled in the art with a convenient road map for implementing the exemplary embodiment or exemplary embodiments. It should be understood that various changes can be made in the function and arrangement of elements without departing from the scope as set forth in the appended claims and the legal equivalents thereof.

What is claimed is:

1. A substrate of the type configured to connect to a ball grid array package having an array pattern, the substrate comprising:
a plurality of conductive pads disposed in said array pattern, the array pattern having a periphery defined by a predetermined edge pattern forming routing channels therebetween; and
a plurality of signal lines connected to a subset of the conductive pads and extending beyond the periphery through the routing channels.

2. The substrate of claim 1, wherein the predetermined edge pattern is a right triangle.

3. The substrate of claim 2, wherein the predetermined edge pattern is a right triangle having a first side defined by a number of rows and a second side defined by a number of layers, wherein the first side is substantially perpendicular to the second side.

4. The substrate of claim 3, wherein the predetermined edge pattern repeats with a periodicity R along the periphery, and wherein R is the number of rows defining the first side of the right triangle.

5. The substrate of claim 4, wherein the number of layers defining the second side of the right triangle is equal to R.

6. The substrate of claim 5, wherein R is between 2 and 8, inclusive.

7. The substrate of claim 4, wherein the array pattern is characterized by an escape efficiency, and wherein the escape efficiency is greater than about 75% for values of R greater than 2.

8. A method of forming a substrate configured to connect to a ball grid array package having an array pattern, comprising:
forming a plurality of conductive pads in accordance with the array pattern such that the array pattern has a periphery defined by a predetermined edge pattern that defines routing channels therebetween; and
forming a plurality of signal lines connected to a subset of the conductive pads and extending beyond the periphery through the routing channels.

9. The method of claim 8, wherein forming the plurality of conductive pads includes forming the predetermined edge pattern as a right triangle.

10. The method of claim 9, wherein the predetermined edge pattern is a right triangle having a first side defined by a number of rows and a second side defined by a number of layers, wherein the first side is substantially perpendicular to the second side.

11. The method of claim 10, wherein the predetermined edge pattern repeats with a periodicity R along the periphery, and wherein R is the number of rows defining the first side of the right triangle.

12. The method of claim 11, wherein the number of layers defining the second side of the right triangle is equal to R.

13. The method of claim 12, wherein R is between 2 and 8, inclusive.

14. The method of claim 11, wherein the array pattern is characterized by an escape efficiency, and wherein the escape efficiency is greater than about 75% for values of R greater than 2.

15. A ball grid array package comprising a plurality of solder balls configured in an array pattern, the array pattern having a periphery defined by a predetermined repeating edge pattern.

16. The package of claim 15, wherein the predetermined edge pattern is a right triangle that repeats with a periodicity R along the periphery, and wherein R is the number layers within the array pattern defining a side of the right triangle.

17. The package of claim 16, wherein R is between 2 and 8, inclusive.

18. The package of claim 16, wherein the array pattern is characterized by an escape efficiency, and wherein the escape efficiency is greater than about 75% for values of R greater than 2.

19. The package of claim 16, wherein the array pattern has a pitch of between about 38 and 42 mils.

20. The package of claim 16, wherein a subset of the solder balls are associated with input/output pins, and wherein the subset is located within a depth R along the periphery of the array.
